(19) United States
(12) Patent Application Publication
(10) Pub. No.: US 2014/0001937 A1
(43) Pub. Date: Jan. 2, 2014

(54) ROTATIONAL LOCKOUT

(71) Applicants: Sean A. Cerniglia, Cool, CA (US); Martin A. Goldstein, Campbell, CA (US)

(72) Inventors: Sean A. Cerniglia, Cool, CA (US); Martin A. Goldstein, Campbell, CA (US)

(73) Assignee: HEWLETT-PACKARD DEVELOPMENT COMPANY, L.P., Houston, TX (US)

(21) Appl. No.: 14/005,255

(22) PCT Filed: Apr. 27, 2011
(86) PCT No.: PCT/US2011/034149

§ 371 Date: Sep. 13, 2013

(51) Int. Cl. H05K 5/02; H05K 13/00

(52) U.S. Cl. CPC H05K 5/0286; H05K 5/0221; H05K 13/00
USPC 312/319.1; 312/333; 29/428

(57) ABSTRACT

An apparatus and method unlock a shaft (42, 142) of a unit (24, 124) for rotation in response to a mechanical reaction between the unit (24, 124) and an enclosure (22, 122) receiving the unit (24, 124) when the unit (24, 124) has been sufficiently inserted into the enclosure (22, 122), whereby rotation of the shaft (42, 142) linearly translates a component of the unit (24, 124) into connection with a component of the enclosure (22, 122).

### BACKGROUND

In many devices or systems, a component of a unit may connect to a component of an enclosure while the unit is within the enclosure, If the components of the unit and the enclosure are not properly aligned during an attempted connection, the components may become damaged.

### BRIEF DESCRIPTION OF THE DRAWINGS

FIG. 1 is a schematic illustration of a connection system with a unit withdrawn from an enclosure according to an example embodiment.

FIG. 2 is a schematic illustration of the connection system of FIG. 1 with the unit inserted into the enclosure according to an example embodiment.

FIG. 3 is a schematic illustration of the connection system of FIG. 1 with the unit inserted into the enclosure and the unit connected to the enclosure according to an example embodiment.

FIG. 4 is a front perspective view of another embodiment of the connection system, unit and enclosure of FIG. 1 with the unit withdrawn from the enclosure according to an example embodiment.

FIG. 5 is a fragmentary perspective view of the unit of FIG. 4 illustrating a connector component in a retracted position according to an example embodiment.

FIG. 6 is a fragmentary perspective view of a rotational lockout mechanism of the unit of FIG. 4 with a rotational lockout mechanism in a locked state according to an example embodiment.

FIG. 7 is an exploded perspective view of the rotational lockout mechanism of FIG. 6 according to an example embodiment.

FIG. 8 is a rear perspective view of the connection system of FIG. 4 with the unit inserted into the enclosure according to an example embodiment.

FIG. 9 is an enlarged fragmentary perspective view of the unit inserted into the enclosure. According to an example embodiments

FIG. 10 is a fragmentary sectional view of the unit inserted into the enclosure with the rotational lockout mechanism in an unlocked state according to an example embodiment.

FIG. 11 is a fragmentary perspective view of the unit of FIG. 8 with a connector component of the unit proximate to a connector component of the enclosure according to an example embodiment.

FIG. 12 is a fragmentary perspective view of the unit of FIG. 8 with the rotational lockout mechanism and the unlocked state and with the connector component in an extended position according to an example embodiment.

FIG. 13 is a fragmentary perspective view of the unit of FIG. 12 with the connector component in the extended position in connection with the connector component of the enclosure according to an example embodiment.

### DETAILED DESCRIPTION OF THE EXAMPLE EMBODIMENTS

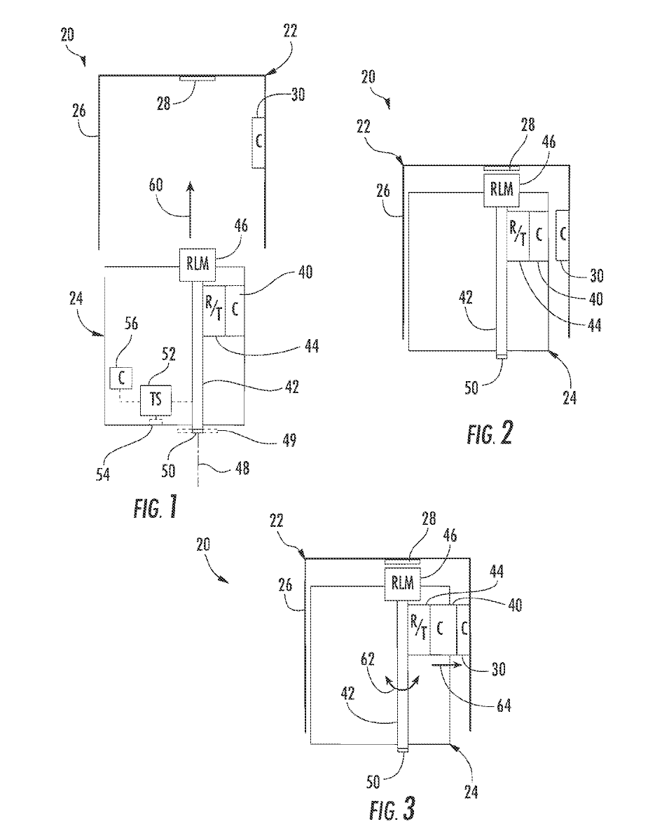

FIGS. 1-3 schematically illustrate a connection system 20 according to an example embodiment. Connection system 20 comprises enclosure 22 and insertable unit 24. As will be described hereafter, connection system 20 facilitates interconnection between components of enclosure 22 and unit 24 while unit 24 is within enclosure 22 and with a low likelihood of damage to such components.

Enclosure 22 comprises one or more structures 26 configured to receive or at least partially surround or enclose unit 24. Enclosure 22 further comprises a mechanical interaction surface 28 and a connector component 30. Mechanical interaction surface 28 comprises one or more surfaces configured to interact with portions of unit 24 to facilitate connection of connector component 30 to portions of unit 24. Connector component 30 comprises a component configured to connect with and interact with a connector component of unit 24. In one embodiment, connector component 30 is configured to facilitate the transmission of electrical signals between unit 24 and enclosure 22. In another embodiment, connector component may be configured to facilitate the transmission of other mediums, such as gases, liquids or mechanical motion or force between unit 24 and enclosure 26.

Unit 24 comprises a unit configured to be inserted into and connected to component 30 of enclosure 28. Unit 24 comprises connector component 40, shaft 42, rotation to translation coupler 44 and rotational lockout mechanism 46. Connector component 40 comprise a component configured to connect to and/or mate with connector component 40 of enclosure 22. In one embodiment, connector component 40 is configured to facilitate the transmission of electrical signals between unit 24 and enclosure 22. In another embodiment, connector component may be configured to facilitate the transmission of other mediums, such as gases, liquids or mechanical motion or force between unit 24 and enclosure 26.

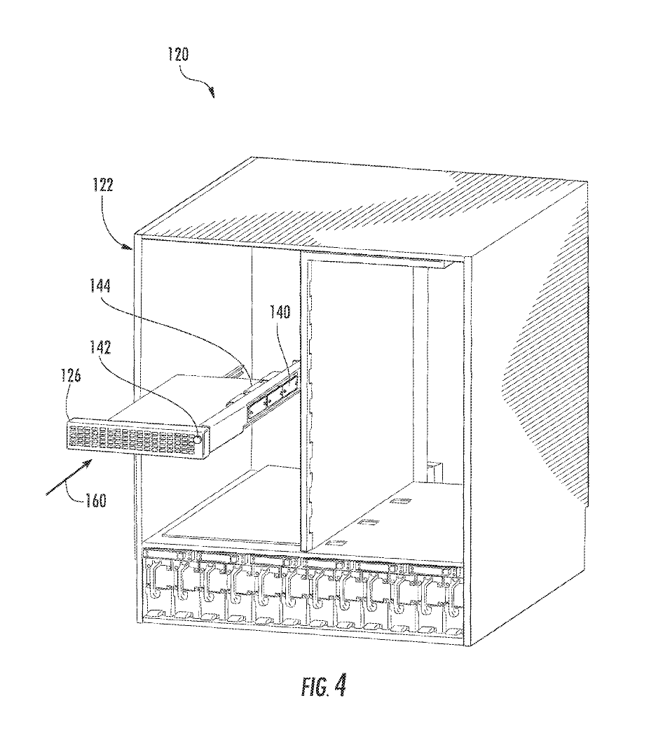

Connector component 40 is movable between a retracted position (shown in FIGS. 1 and 2) and an extended position (shown in FIG. 3). In the retracted position, connector component 40 is sufficiently recessed or retracted into unit 24 such that connect component 40 is not completely connect with connector 30 and is less susceptible to damage during insertion of unit 24 into enclosure 22. In the extended position, connector component 40 sufficiently projects from unit 24 so as to completely connect with connector 30 of enclosure 22. One embodiment, connector component 40 may be movably supported by one or more guides, tracks, channels, bearings or the like.

Shaft 42 comprises an elongate member rotationally supported by enclosure 22 for rotation about its axis 48. Shaft 42 is operably connected to rotation to translation coupler 44 which transmitter converts rotational motion from shaft 42 into linear or translational motion or movement to linearly translate controller component 40 between the extended and retracted positions. Shaft 42 is further operably coupled to rotational lockout mechanism 46 which controls or limits rotational shaft 42. In one embodiment, shaft 42 may include a handle 49 for facilitating manual tool less rotation of shaft 42. In another embodiment, shaft 42 may include an interface 50 for interaction with a tool, such as an Allen wrench, screwdriver and the like, for rotation of shaft 42. In yet other embodiments, shaft 42 may be operably coupled to an optional torque source 52 (schematically illustrated) such as a motor (with associated worm gear-bevel gear arrangement, belt and pulley arrangement, chain and sprocket arrangement or the like) or rotating shaft 42 in response to actuation of a switch 54 or in response to control signals from an optional controller 56.

Rotation to translation coupler 44 comprise one or more mechanisms operably coupling shaft 42 to connector 40 such that rotation of shaft 42 linearly translates connector component 40 between the extended position and a retracted position. In one embodiment, coupler 44 may move connector component 40 in one direction, wherein a resilient bias, such as a spring, resiliently moves connector component 40 in the other direction. In another embodiment, coupler 44 may move connector 140 in each of two opposite directions. According to one embodiment, rotation to translation coupler 44 may comprise one or more cam and cam follower arrangements. In another embodiment, rotation to translation coupler 44 may comprise other mechanical arrangements such as an incline, a chain and sprocket arrangement or a belt and pulley arrangement for converting rotational motion to linear motion.

Rotational lockout mechanism 46 comprises a mechanism or arrangement of members configured to lock shaft 42 against rotation and to unlock shaft 42 for rotation in response to a mechanical reaction between enclosure 22 and unit 24 that occurs when unit 24 has been sufficiently inserted into enclosure 22 such that connect component 40 is sufficiently proximate to or aligned with connector component 30. In the example illustrated, the mechanical reaction occurs when portions of rotational lockout mechanism 46 physically contact surface 28. For purposes of this disclosure, the term “mechanical reaction” means that mechanical forces solely resulting from the manual force applied to unit 24 to push or insert unit 24 into enclosure 22 (and against surface 28) are transmitted to and used to physically move members of rotational lockout mechanism 28 so as to activate or actuate rotational lockout mechanism 46 to an unlocked state. In other words, actuation of rotational lockout mechanism 46 does not utilize external power such as from a cylinder assembly, motor, solenoid and the like to move mechanism 46 between locked and unlocked states and does not employ optical or electrical sensors or switches for detecting when unit 24 has been sufficiently inserted into enclosure 22. Such a mechanical reaction may be similar in nature to the insertion of a key into a padlock, wherein the insertion force of the key into the padlock moves various tumblers to allow the key to be subsequently rotated to unlock the padlock.

FIGS. 1-3 further illustrate an example process or method by Which unit 24 is inserted into and connected to enclosure 22. As shown by FIG. 1, while connector component 40 of unit 24 is in the recess or retracted position, unit 24 is inserted into enclosure 26 by being moved in the direction indicated by arrow 60. As shown by FIG. 2, such insertion continues until rotational lockout mechanism 46 physically contacts surface 28 of enclosure. While rotational lockout mechanism 46 is in physical contact with surface 28, connector component 40 is in sufficient proximity or alignment with connector component 30 of enclosure 22 for subsequent connection to connector component 30. The physical contact or physical interaction between rotational lockout mechanism 46 and surface 28 causes a mechanical reaction whereby the manual force is used to press rotation lockout mechanism 46 against surface 28 also causes one or more mechanical members of rotational lockout mechanism 46 to also move so as to actuate rotational lockout mechanism 46 from a locked state, preventing rotation of shaft 42, to and unlocked state, allowing rotation of shaft 42.

As shown by FIG. 3, once rotational lockout mechanism 46 has been activated to an unlocked state as a result of the mechanical reaction between rotational lockout mechanism 46 and surface 28, shaft 42 is rotated about its axis 48 in one of two possible directions as indicated by arrows 62. Rotation of shaft 42 generates circular motion and torque. Rotation to translation coupler 44 converts the rotational motion and torque provided by the rotation of shaft 42 to linear translational motion so as to move connector component 40 in the direction indicated by arrow 64, perpendicular to direction 60 and axis 48, from a recessed or retracted position to a projecting or extended position and into connection or contact with connector component 30. Because rotational lockout mechanism 46 potentially inhibits or prevents rotation of shaft 42 and therefore prevents or inhibits extension of connector component 40 until connector component 40 is sufficiently proximate to and aligned with connector component 30, rotational lockout mechanism 46 reduces the likelihood of accidental damage to connector components 40 and 30, which might otherwise result from premature attempted connection of such components. This is especially beneficial in some embodiments where connection components 30 and 40 cannot be visibly seen or cannot be visibly aligned with one another when unit 24 is inserted into enclosure 22 (a blind connection, insertion or assembly action).

Disconnection and withdrawal of unit 24 from enclosure 22 occurs by sequencing through the above-mentioned steps in an opposite manner. in particular, shaft 42 is rotated, moving or allowing connector component 40 to move to the retracted or recessed position in which component 40 is disconnected from component 30. Thereafter, unit 24 is withdrawn from enclosure 22.

FIGS. 4-14 illustrate connection system 120, another embodiment of connection system 20 shown in FIGS. 1-3. Connection system 120 comprises enclosure 122 and insertable unit 124. As with connection system 20, connection system 120 facilitates interconnection between components of enclosure 122 and unit 124 while unit 124 is within enclosure 122 and with a low likelihood of damage to such components. In the example illustrated, connection system 120 comprises a computer blade system, wherein enclosure 122 comprises a computer blade enclosure or receptacle configured to receive a plurality of computer blades and wherein unit 124 comprises one of the computer blades. In other embodiments, connection system 120 may be embodied as other devices.

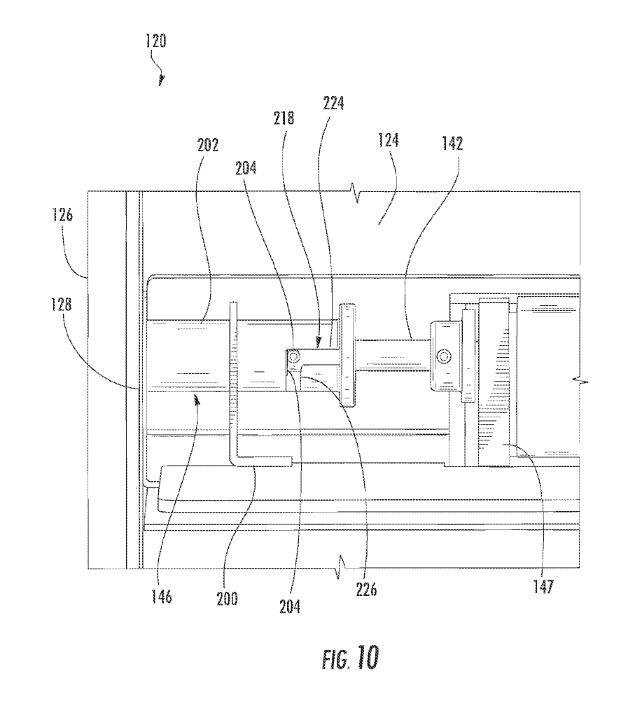

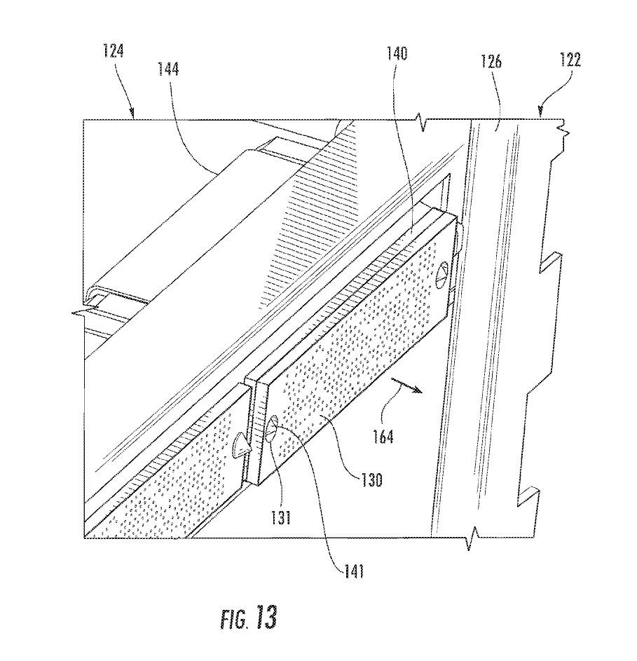

Enclosure 122 comprises one or more structures 126 configured to receive or at least partially surround or enclose unit 124. Enclosure 122 farther comprises a mechanical interaction surface 128 (shown in FIGS. 8-10) and a connector component 130 (shown in FIG. 11). Mechanical interaction surface 128 comprises one or more surfaces configured to interact with portions of unit 124 to facilitate connection of connector component 130 to portions of unit 124. Connector component 130 comprises a component configured to connect with and interact with a connector component of unit 124. In the example illustrated, connector component 130 is configured to facilitate the transmission of electrical signals between unit 124 and enclosure 122. In the example illustrated, connector component 130 includes alignment apertures 131 configured to receive alignment structures such as alignment pins of a connector component of unit 124. In other embodiments, connector component 130 may be configured to facilitate the transmission of other mediums, such as gases, liquids or mechanical motion or force between unit 124 and enclosure 126.

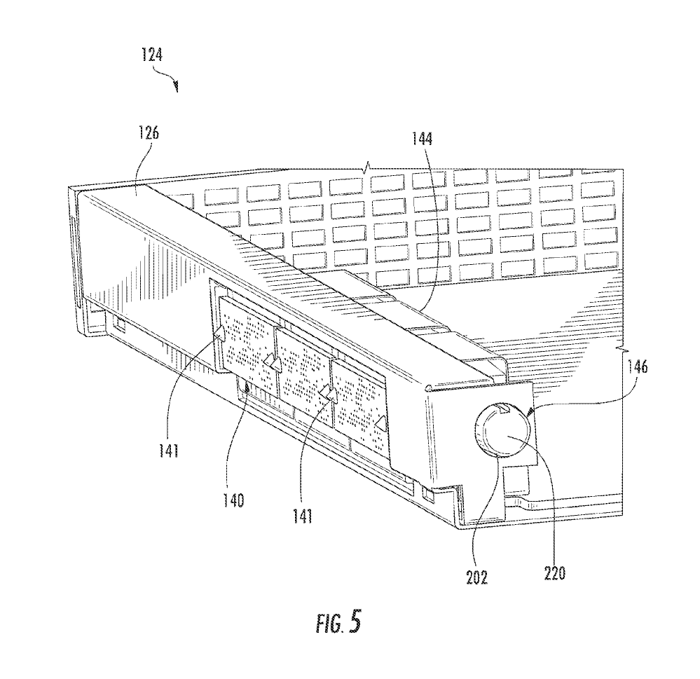

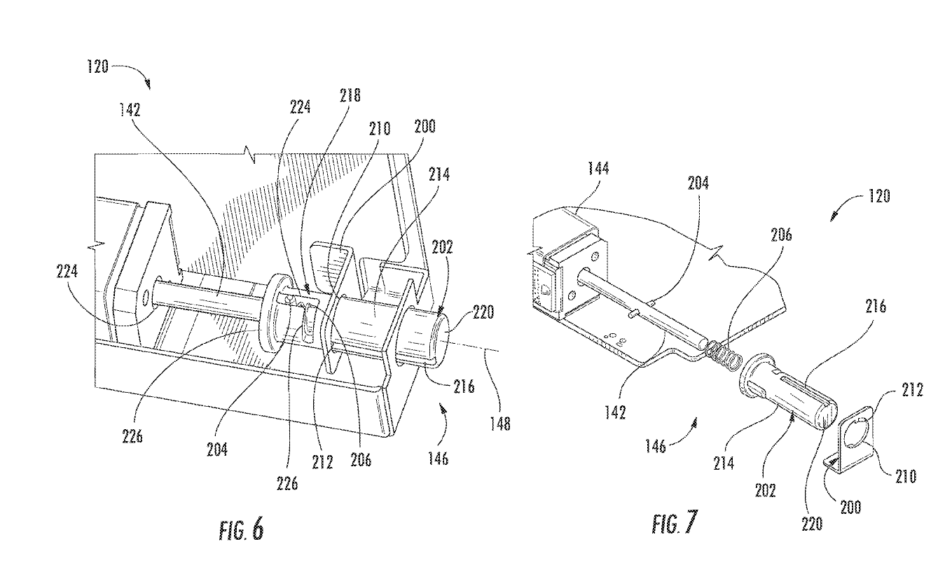

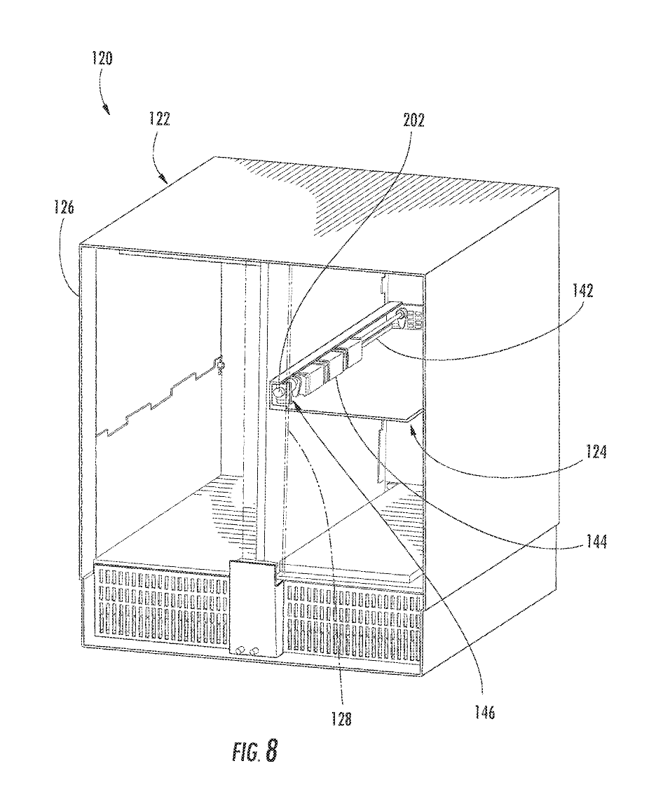

Unit 124 comprises a unit configured to be inserted into and connected to component 130 of enclosure 128. Unit 124 comprises connector component 140, shaft 142, rotation to translation coupler 144, rotational lockout mechanism 146 (shown in FIG. 5) and secondary unit locks 147. Connector component 140 comprise a component configured to connect to and/or mate with connector component 130 of enclosure 122. In the example illustrated, connector component 140 is configured to facilitate the transmission of electrical signals (signals representing data or controls) between unit 124 and enclosure 122. In the example illustrated, connector component 140 includes alignment projections or pins 141 configured to be received within alignment apertures 131 of connector component 130. In other embodiments, connector component 140 may include alignment apertures while component 130 includes alignment projections or pins. In another embodiment, connector component 140 may be configured to facilitate the transmission of other mediums, such as gases, liquids or mechanical motion or force between unit 124 and enclosure 126.

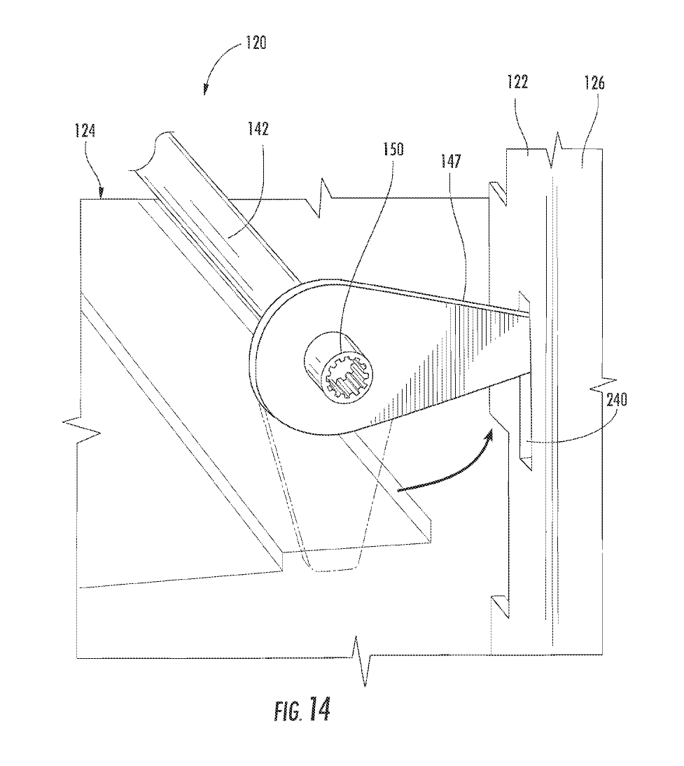

Connector component 140 is movable between a retracted position (shown in FIGS. 5 and 11) and an extended position (shown in FIGS. 12 and 13). In the retracted position, connector component 140 is sufficiently recessed or retracted into unit 124 such that connect component 140 does not completely connect with connector 130 and is less susceptible to damage during insertion of unit 124 into enclosure 122. In the extended position, connector component 140 sufficiently projects from unit 124 so as to completely connect with connector 130 of enclosure 122. One embodiment, connector component 140 may be movably supported by one or more guides, tracks, channels, bearings or the like.

Shaft 142 comprises an elongate member rotationally supported by enclosure 122 for rotation about its axis 148. Shaft 142 is operably connected to rotation to translation coupler 144 which transmitter converts rotational motion from shaft 142 into linear or translational motion or movement to linearly translate controller component 140 between the extended and retracted positions. Shaft 142 is further operably coupled to rotational lockout mechanism 146 which controls or limits rotation of shaft 142. In the example illustrated, shaft 142 includes an interface 150 (shown in FIG. 14) for interaction with a tool, such as an Allen wrench, screwdriver and the like, for rotation of shaft 142. In other embodiments, shaft 142 may include a handle such as handle 49 shown in FIG. 1 for facilitating manual tool less rotation of shaft 42. In yet other embodiments, shaft 142 may be operably coupled to an optional torque source 52 (schematically illustrated in FIG. 1) such as a motor (with associated worm gear-bevel gear arrangement, belt and pulley arrangement, chain and sprocket arrangement or the like) for rotating shaft 142 in response to actuation of a switch 54 or in response to control signals from an optional controller 56 (shown in FIG. 1).

Rotation to translation coupler 144 comprise one or more mechanisms operably coupling shaft 142 to connector 140 such that rotation of shaft 142 linearly translates connector component 140 between the extended position and a retracted position. In one embodiment, coupler 144 may move connector component 140 in one direction, wherein a resilient bias, such as a spring, resiliently moves connector component 40 in the other direction. In another embodiment, coupler 144 may move connector 140 in each of two opposite directions. According to one embodiment, rotation to translation coupler 144 may comprise one or more cam and cam follower arrangements. In another embodiment, rotation to translation coupler 144 may comprise other mechanical arrangements such as an incline, a chain and sprocket arrangement or a belt and pulley arrangement for converting rotational motion to linear motion.

Rotational lockout mechanism 146 comprises a mechanism or arrangement of members configured to lock shaft 142 against rotation and to unlock shaft 142 for rotation in response to a mechanical reaction between enclosure 122 and unit 124 that occurs when unit 124 has been sufficiently inserted into enclosure 122 such that connect component 140 is sufficiently proximate to or aligned with connector component 130. In the example illustrated, the mechanical reaction occurs when portions of rotational lockout mechanism 146 physically contact surface 128. As with rotational lockout mechanism 46, rotational lockout mechanism 146 uses and transmits mechanical forces resulting from the manual force applied to unit 24 to push or insert unit 24 into enclosure 22 (and against surface 28) to physically move members of rotational lockout mechanism 146 so as to activate or actuate rotational lockout mechanism 146 to an unlocked state. In other words, actuation of rotational lockout mechanism 146 does not utilize external power such as from a hydraulic or pneumatic cylinder assembly, motor, solenoid and the like to move mechanism 46 between locked and unlocked states and does not employ optical, electrical or other types of non-manual powered sensors or switches for detecting when unit 124 has been sufficiently inserted into enclosure 122.

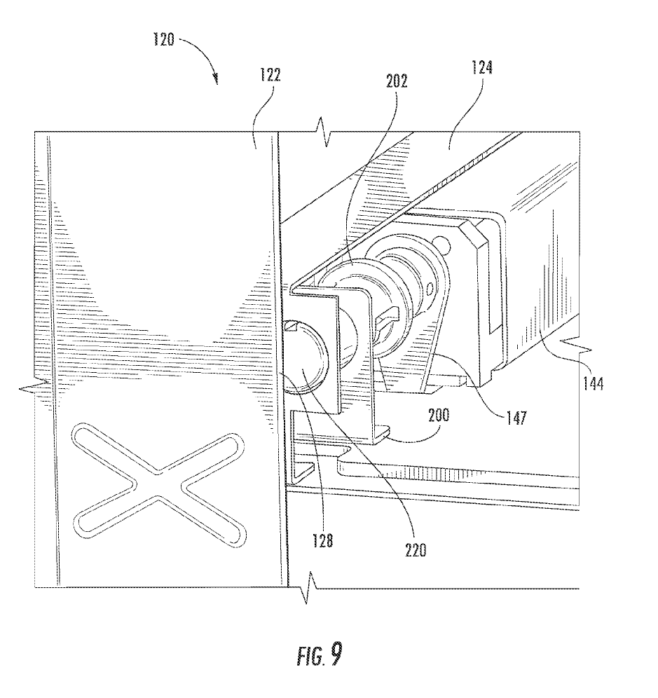

FIGS. 6 and 7 illustrate rotational lockout mechanism 146 in more detail. As shown by FIGS. 6 and 7, rotational lockout mechanism 146 comprises keyed guide 200, plunger 202, projection 204 and bias 206. Keyed guide 200 comprises a structure fixed or extending from a frame or housing of unit 24 and configured to interact with plunger 202, allowing plunger 202 to translate along its axis or center line while inhibiting rotation of plunger 202 about its axis or center line. In the example illustrated, keyed guide 200 comprises an opening 210 having a notch 212 forming a keyway.

Plunger 202 comprise a member key to guide 200 against rotation and configured to linearly translate through the keyway formed by opening 210 in the notch 212. In the example illustrated, plunger 202 includes tubular portion 214, projection 216 and slot 218. Tubular portion 214 slidably receives an end of shaft 142, allowing tubular portion 2142 slide relative to shaft 142. Tubular portion 214 has an end 220 configured to physically contact surface 128 of enclosure 122 upon sufficient insertion of unit 124 into enclosure 122. Tubular portion 214 has an outer profile substantially matching that of hole 210. In other embodiments, tubular portion 214 may have other outer profiles.

Projection 216 asymmetrically extends from tubular portion 214 and is configured to slide through notch 212. In other embodiments, the keying relationship may be reversed wherein guide 200 includes a projection while plunger 202 includes an elongate channel slidably receiving the projection. In yet other embodiments, notch 212 and projection 216 may be omitted, wherein other keying relationships are provided such as where both hole 210 and the outer profile tubular portion 214 have non-circular shapes.

Slot 218 extends through the outer profile to an interior of tubular portion 214. Slot 218 receipts projection 204. Slot 218 includes art axial portion 224 and a circumferential portion 226. Axial portion 224 axially extends along axis 148 of shaft 142, receives projection 204 when rotational lockout mechanism 146 is in a locked position or state and allows plunger 202 to move axially along shaft 142 while preventing substantial rotation of shaft 142 relative to plunger 202. Circumferential portion 226 extend at least partially about shaft 142. Circumferential portion 226 receipts projection 204 when rotational lockout mechanism is in the unlocked position or state and allows shaft 142 and projection 204 to be rotated about axis 148 relative to plunger 202.

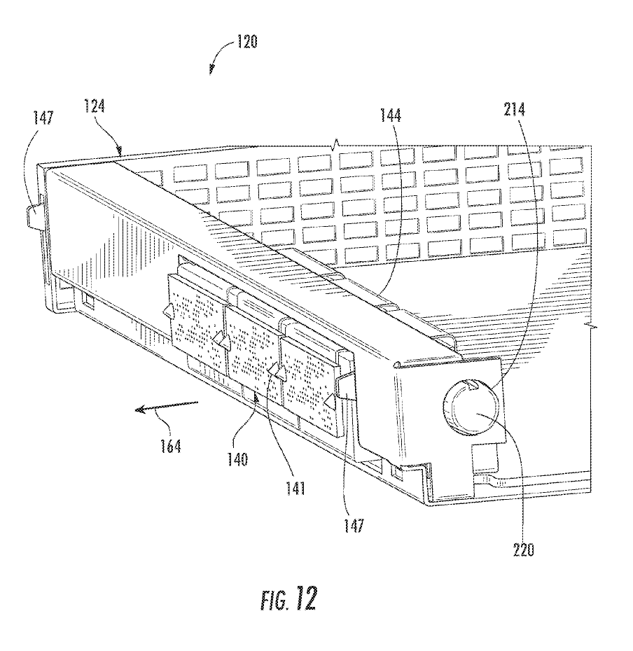

Projection 204 comprises a protuberance extending from shaft 142 into slot 218. In the example illustrated, projection 204 is formed by pin fit in place through a bore in shaft 142. In other embodiments, pin 204 may be integrally formed as a single unitary body, welded, fused or otherwise joined to shaft 142 so as to rotate with shaft 142. Projection 204 cooperates and interacts with slot 218 such that plunger 202 is movable relative to shaft 142 between (1) a first locked position (shown in FIG. 6) in which plunger 202 locks shaft 142 against rotation relative to plunger 202 when projection 204 is within axial portion 224 and (2) a second unlocked position (shown in FIG. 10) in which shaft 142 is rotatable relative to plunger 202 when projection 204 is within circumferential portion 226.

Bias 206 comprises one or more structures configured to resiliently urge bias plunger 202 towards the first locked position in which plunger 202 projects beyond an end of unit 124 by a greater extent as compared to when plunger 202 is in the second position and in which projection 204 is contained within axial portion 224 of slot 218. in the example illustrated, bias 206 comprises a compression spring captured between projection 204 and an internal blind hole (not shown), shoulder or other surface of tubular portion 214 of plunger 202. In other embodiments, bias 206 may be provided by other arrangements. For example, bias 206 method for comprising compression spring between an end of shaft 142 and an axially facing surface of an internal blind hole of plunger 202. In another embodiment, bias 206 may comprise a compression spring extending between surface 224 and surface 226 or between service 224 and projection 204 (as seen in FIG. 6). In yet other embodiments, bias 206 may have other locations and utilize other forms of springs or biasing structures.

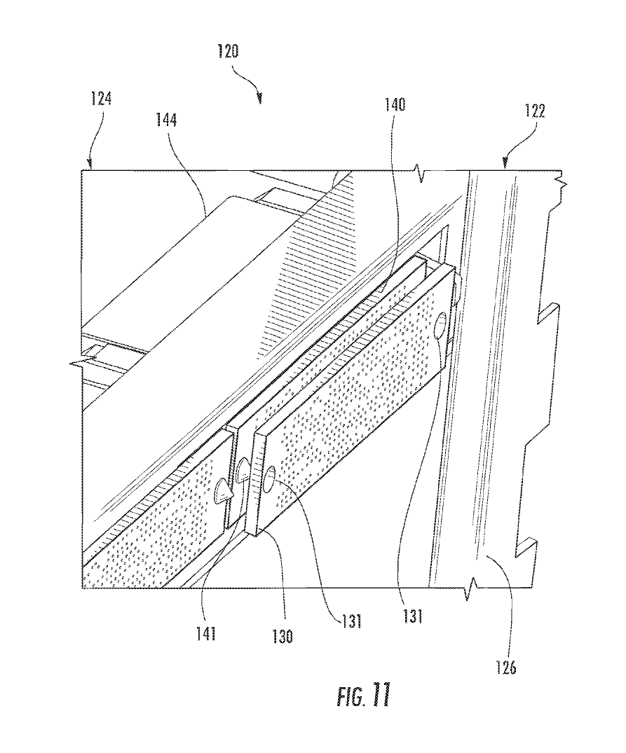

Secondary unit locks 147, (shown in FIGS. 9, 10 and 14) comprise latches, bars or other structures operably coupled to shaft 142 so as to move, in response to rotation of shaft 142, between a locking state in which the unit 124 is locked or retained relative to enclosure 122 when in the enclosure 122 and an unlocked state. In the example illustrated, locks 147 comprise projections fixed to shaft 142 and extending from shaft 142. Secondary unit locks 147 include both a front lock 147 (shown in FIG. 14) and a rear lock 147 (shown in FIG. 9). As shown by FIG. 9 and in broken lines in FIG. 14, in the unlocked state or position, locks 147 are contained within or do not sufficiently project beyond unit 124 to interact with enclosure 22. As shown by FIGS. 12 and 14, in the locked state or position, locks 147 sufficiently project beyond unit 124 so as to extend into corresponding receiving slots or openings 240 (one of which is shown in FIG. 14) to inhibit or prevent movement and withdrawal of unit 124 from enclosure 122. In addition to retaining unit 124 in enclosure 122, locks 147 additionally provide a path for shock and loads instead of such loads and shocks extending through connection components 140 and 130. When unit 124 is withdrawn or removed from enclosure 122, secondary locks 147 further prevent or inhibit insertion of unit 124 into enclosure 122 when connector component 140 is inadvertently in the extended position, further inhibiting accidental damage to connector component 140. In other embodiments, one or both of secondary locks 147 may be omitted.

FIGS. 4, 5, 6 and 8-13 further illustrate an example process or method by which unit 124 is inserted into and connected to enclosure 122. As shown by FIGS. 4-6, while connector component 140 of unit 124 is in the recessed or retracted position, unit 124 is inserted into enclosure 122 by being moved in the direction indicated by arrow 160. As shown by FIGS. 8-11, such insertion continues until end 220 of plunger 202 physically contacts surface 128 of enclosure 122. As shown by FIG. 11, while plunger 202 is in physical contact with surface 128, connector component 140 is or is moved into sufficient proximity or alignment with connector component 130 of enclosure 122 for subsequent connection to connector component 130. The physical contact or physical interaction between end 220 of plunger 202 and surface 128 causes plunger 202 to move from the state shown in FIG. 6 to the state shown in FIG. 10 against bias 206, whereby projection 204 is relocated from axial portion 224 into circumferential portion 226 of slot 218, allowing shaft 142 to be rotated. As shown by FIGS. 12 and 13, once rotational lockout mechanism 146 has been activated to an unlocked state as a result of the mechanical reaction between plunger 202 and surface 28, shaft 142 is rotated about its axis 148 to generate circular motion and torque, Rotation to translation coupler 144 converts the rotational motion and torque provided by the rotation of shaft 142 to linear translational motion so as to move connector component 140 in the direction indicated by arrow 164, perpendicular to direction 160 and axis 148, from a recessed or retracted position to a projecting or extended position and into connection or contact with connector component 130. Because rotational lockout mechanism 146 potentially inhibits or prevents rotation of shaft 142 and therefore prevents or inhibits extension of connector component 140 until connector component 140 is sufficiently proximate to an aligned with connector component 130, rotational lockout mechanism 146 reduces the likelihood of accidental damage to connector components 140 and 130, which might otherwise result from premature attempted connection of such components. In the example illustrated in which connection components 130 and 140 cannot be visibly seen or visibly aligned while unit 124 is inserted into enclosure 122, the alignment indication provided by rotational lockout mechanism 146 offers enhanced protection against accidental damage to connection components 130, 140 during an attempted connection.

Disconnection and withdrawal of unit 124 from enclosure 122 occurs by sequencing through the above-mentioned steps into an opposite manner. In particular, shaft 142 is rotated, moving or allowing connector component 140 to move to the retracted or recessed position in which component 140 is disconnected from component 130. Thereafter, unit 124 is withdrawn from enclosure 122.

Although the present disclosure has been described with reference to example embodiments, workers skilled in the art will recognize that changes may be made in form and detail without departing front the spirit and scope of the claimed subject matter. For example, although different example embodiments may have been described as including one or more features providing one or more benefits, it is contemplated that the described features may be interchanged with one another or alternatively be combined with one another in the described example embodiments or in other alternative embodiments. Because the technology of the present disclosure is relatively complex, not all changes in the technology are foreseeable. The present disclosure described with reference to the example embodiments and set forth in the following claims is manifestly intended to be as broad as possible. For example, unless specifically otherwise noted, the claims reciting a single particular element also encompass a plurality of such particular elements.

1. An apparatus comprising:
a unit insertable into an enclosure having a first component, the unit comprising:
a second component;
a shaft operably coupled to the second component to linearly translate the second component between a first state connected to the first component and a second state disconnected from the first component in response to rotation of the shaft; and
a rotational lockout mechanism configured to lock the shaft against rotation and to unlock the shaft for rotation in response to a mechanical reaction between the enclosure and the unit that occurs when the unit has been sufficiently inserted into the enclosure such that the second component is proximate the first component.

2. The apparatus of claim 1, wherein rotational lockout mechanism comprises:
a keyed guide associated with the unit; and
a movable plunger keyed to the guide against rotation and configured to contact a fixed physical stop surface of the enclosure upon insertion of the unit into the enclosure, wherein the plunger is movable relative to the shaft between a first position in which the plunger locks the shaft against rotation and a second position in which the shaft is rotatable relative to the plunger.

3. The apparatus of claim 2, when the plunger is resiliently biased toward the first position and wherein insertion of the unit into the enclosure on the plunger is in contact with the fixed physical stop surface moves the plunger against a bias to the second position.

4. The apparatus of claim 2, wherein the plunger includes a slot having an axial portion axially along the shaft and a circumferential portion at least partially about the shaft and wherein the shaft includes a projection movable within the slot.

5. The apparatus of claim 4 further comprising a spring captured between the projection and the plunger to resiliently bias the plunger towards the first position.

6. The apparatus of claim 1 further comprising a unit lock that, in response to rotation of the shaft, is actuatable between a locking state in which the unit is locked to the enclosure when in the enclosure and an unlocked state.

7. The apparatus of claim 6 wherein the unit lock comprises a latch configured to prevent insertion of the unit into enclosure when the lock is in the locking state prior to insertion of the unit into the enclosure.

8. The apparatus of claim 1, wherein the unit is insertable into the enclosure in a first direction, wherein the shaft is rotatable about an axis parallel to the first direction and wherein the second component is linearly translatable in a second direction perpendicular to the first direction.

9. The apparatus of claim 1, wherein the first component and the second opponent comprise first and second electrical connectors, respectively.

10. The apparatus of claim 1, wherein alignment of the first component and the second component are not visible to an operator when the unit is within the enclosure.

11. The apparatus of claim 1 further comprising the enclosure having the first component.

12. The apparatus of claim 11, wherein the enclosure comprises a computer blade enclosure configured to receive a plurality of computer blades and wherein the unit comprises one of the computer blades.

13. A method comprising:
inserting a unit into an enclosure having a first component, the unit having a second component;
unlocking a shaft for rotation automatically response to a mechanical reaction between the unit in the enclosure upon a predetermined extent of insertion of the unit into the enclosure; and
rotating shaft to linearly translate the second component into connection with the first component.

14. The method of claim 13 further comprising locking the shaft against rotation using a keyed guide associated with the unit and a movable plunger keyed to the guide against rotation and configured to contact a fixed physical stop surface of the enclosure upon insertion of the unit into the enclosure, wherein the plunger is moved relative to the shaft between a first position in which the plunger locks the shaft against rotation and a second position in which the shaft is rotatable relative to the plunger.

15. The method of claim 13, wherein the enclosure comprises a computer blade enclosure configured to receive a plurality of computer blades and wherein the unit comprises one of the computer blades.
